(19) United States
(12) Patent Application Publication
(10) Pub. No.: US 2017/0189934 A1
(43) Pub. Date: Jul. 6, 2017

(54) OLED Display Panel And Method For Preparing The Same

(71) Applicant: Shenzhen China Star Optoelectronics Technology Co. Ltd., Shenzhen, Guangdong (CN)

(72) Inventor: Cheng ZOU, Shenzhen, Guangdong (CN)

(73) Assignee: Shenzhen China Star Optoelectronics Technology Co. Ltd., Shenzhen, Guangdong (CN)

(21) Appl. No.: 14/892,326

(22) PCT Filed: Oct. 26, 2015
(86) PCT No.: PCT/CN2015/092810

§ 371 Date: Nov. 19, 2015

(30) Foreign Application Priority Data
Sep. 28, 2015 (CN) 201510628785.1

(51) Int. Cl. B05D 1/04; H01L 51/00; G02F 1/1333

(52) U.S. Cl. CPC B05D 1/04; G02F 1/1333; H01L 51/0002; H01L 51/0076

(57) ABSTRACT

The disclosure is related to a method for preparing an OLED display panel, comprising: providing a substrate; disposing a spray device above the substrate, and applying a forward voltage to the spray device; applying a reverse voltage to a section of the substrate on which organic material being going to be deposited, and applying a forward voltage outside the section; the spray device spraying organic material in fog form, such that the organic material in fog form depositing on the section. The disclosure further provides an OLED display panel prepared by the method. In the disclosure, sub pixels can be prepared without masks, the spray device sprays out the organic material in fog form by electro spraying, and a higher accuracy is not necessary for the spray device, which sprays by electro spraying, such that the cost is significantly decreased.

### TECHNICAL FIELD

The disclosure is related to the field of display technologies, and more particularly, to an OLED display panel and a method for preparing the same.

### RELATED ART

Organic light emitting displays (OLED) are panel displays having great potentials, they have excellent display properties, are self-luminous, have simple structures, are light and thin, have rapid response speed, have wide visual angles, have low power consumption and can achieve flexible displaying, such that they are named as “fantastic displays” and are known as mainstream displays in next generation.

Currently, the method for preparing OLED elements in OLED displays mainly comprises: 1. thermal evaporation coating, which needs masks for forming certain shapes or pixels; 2. ink jet printing, which needs to use nozzles having higher accuracy. In the two methods, the usage of coating materials are low in thermal evaporation coating and additional masks are needed; ink jet printing needs to use nozzles having higher accuracy, which increases the cost . . . .

### SUMMARY

In order to solve the above technical problem, one purpose of the disclosure is to provide a method for preparing an OLED display panel, comprising: providing a substrate; disposing a spray device above the substrate, and applying a forward voltage to the spray device; applying a reverse voltage to a section of the substrate on which organic material being going to be deposited, and applying a forward voltage outside the section of substrate on which organic material being going to be deposited; the spray device spraying organic material in fog form, such that the organic material in fog form depositing on the section of the substrate on which organic material being going to be deposited.

Further, applying a reverse voltage to a section of the substrate on which red organic material is going to be deposited, and applying a forward voltage to the section outside the section of the substrate on which red organic material is going to be deposited; the spray device spraying red organic material in fog form, such that the red organic material in fog form is deposited on the section of the substrate on which red organic material is going to be deposited.

Further, the spray device comprises a first liquid supplying pipe and a first nozzle disposed beneath the first liquid supplying pipe; wherein red organic material is disposed inside the first liquid supplying pipe, and the red organic material is atomized and sprayed out by applying a forward voltage to the first nozzle.

Further, applying a reverse voltage to a section of the substrate on which green organic material is going to be deposited, and applying a forward voltage to the section outside the section of the substrate on which green organic material is going to be deposited; the spray device spraying green organic material in fog form, such that the green organic material in fog form is deposited on the section of the substrate on which green organic material is going to be deposited.

Further, the spray device comprises a second liquid supplying pipe and a second nozzle disposed beneath the second liquid supplying pipe; wherein green organic material is disposed inside the second liquid supplying pipe, and the green organic material is atomized and sprayed out by applying a forward voltage to the second nozzle.

Further, applying a reverse voltage to a section of the substrate on which blue organic material is going to be deposited, and applying a forward voltage to the section outside the section of the substrate on which blue organic material is going to be deposited; the spray device spraying blue organic material in fog form, such that the blue organic material in fog form is deposited on the section of the substrate on which blue organic material is going to be deposited.

Further, the spray device comprises a third liquid supplying pipe and a third nozzle disposed beneath the third liquid supplying pipe; wherein blue organic material is disposed inside the third liquid supplying pipe, and the blue organic material is atomized and sprayed out by applying a forward voltage to the third nozzle.

Further, the spray device sprays out the organic material in fog form by electro spraying.

The disclosure further provides an OLED display panel prepared by the above method.

Advantages of the disclosure: according to the method for preparing an OLED display panel in the disclosure, sub pixels can be prepared without masks, the spray device sprays out the organic material in fog form by electro spraying, and a higher accuracy is not necessary for the spray device, which sprays by electro spraying, such that the cost is significantly decreased.

### BRIEF DESCRIPTION OF THE DRAWINGS

In order to more clearly illustrate the embodiments of the disclosure, the accompanying drawings for illustrating the technical solutions and the technical solutions of the disclosure are briefly described as below.

FIG. 1 is a schematic view of preparing a red sub pixel of an OLED display panel according to the embodiment the disclosure;

FIG. 2 is a schematic view of preparing a green sub pixel of an OLED display panel according to the embodiment the disclosure; and

FIG. 3 is a schematic view of preparing a blue sub pixel of an OLED display panel according to the embodiment the disclosure.

### DETAILED DESCRIPTION

The following description with reference to the accompanying drawings is provided to clearly and completely explain the exemplary embodiments of the disclosure. It is apparent that the following embodiments are merely some embodiments of the disclosure rather than all embodiments of the disclosure. According to the embodiments in the disclosure, all the other embodiments attainable by those skilled in the art without creative endeavor belong to the protection scope of the disclosure.

In the figures, in order to clearly identify the elements, the thicknesses of the layers and sections are enlarged. Identical notations can be referred as identical elements in the description and the figures.

It can be realized that the terms “first”, “second” and “third” are configured for describing each elements, and the elements are not limited by the terms. These terms merely distinguish one element form another element.

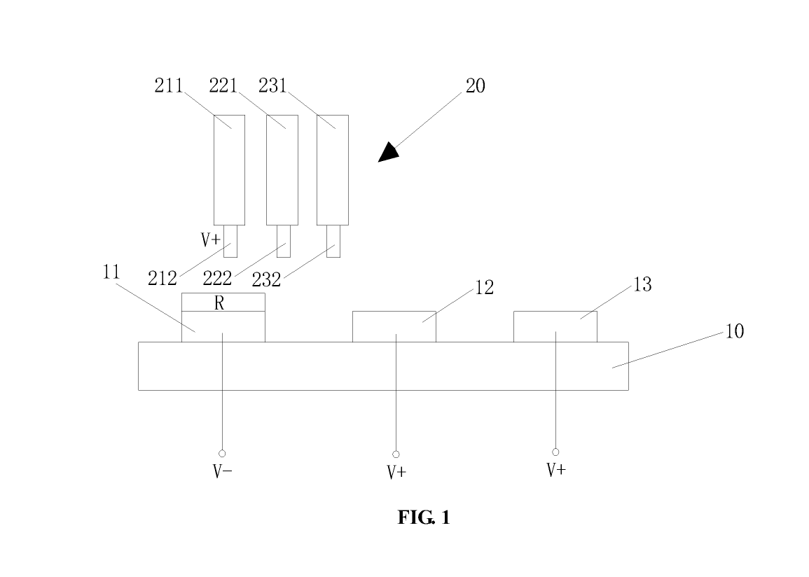

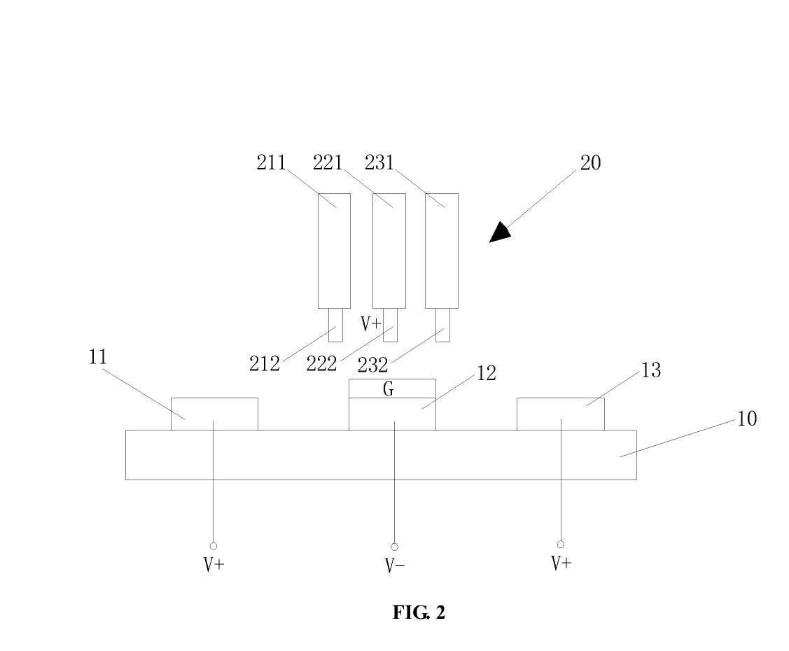

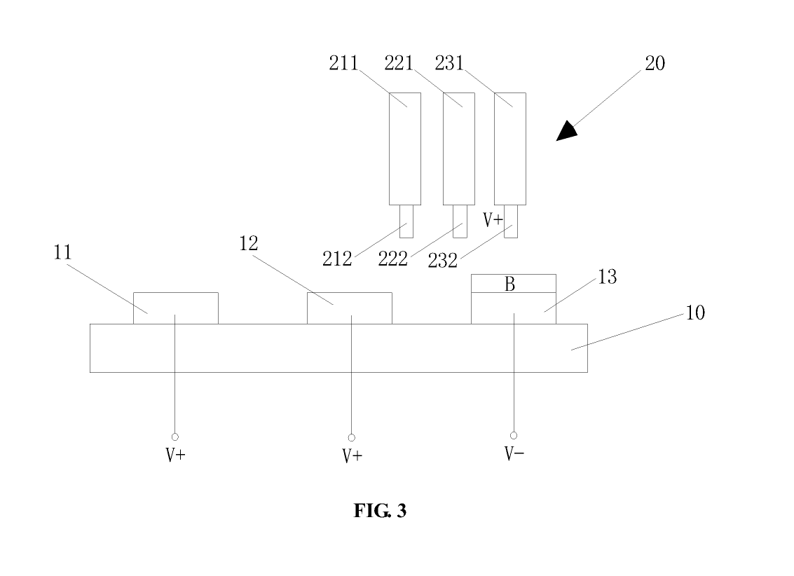

FIG. 1 is a schematic view of preparing a red sub pixel of an OLED display panel according to the embodiment the disclosure. FIG. 2 is a schematic view of preparing a green sub pixel of an OLED display panel according to the embodiment the disclosure. FIG. 3 is a schematic view of preparing a blue sub pixel of an OLED display panel according to the embodiment the disclosure.

Referring to FIGS. 1-3, according to the embodiment of the disclosure, a spray device 20 comprises: a first liquid supplying pipe 211 and a first nozzle 212 disposed beneath the first liquid supplying pipe 211; a second liquid supplying pipe 221 and a second nozzle 222 disposed beneath the second liquid supplying pipe 221; a third liquid supplying pipe 231 and a third nozzle 232 disposed beneath the third liquid supplying pipe 231. In the disclosure, the amount of liquid supplying pipes and nozzles are not limited to the figures, for example, when an OLED display panel is constituted by four pixels (e.g. RGBW sub pixels), the spray device 20 can comprises 4 liquid supplying pipes and 4 nozzles.

In the embodiment, red organic material is disposed inside the first liquid supplying pipe 211, and the red organic material can be atomized and sprayed out by the first nozzle 212 by electro spraying; green organic material is disposed inside the second liquid supplying pipe 221, and the green organic material can be atomized and sprayed out by the second nozzle 222 by electro spraying; blue organic material is disposed inside the third liquid supplying pipe 231, and the blue organic material can be atomized and sprayed out by the third nozzle 232 by electro spraying; however, the disclosure is not limited thereto.

Referring to FIG. 1-3, when preparing an OLED display panel, first, a substrate 10 is provided. In this embodiment, the substrate 10 is a transparent glass substrate, but the disclosure is not limited thereto, for example, the substrate 10 can be a transparent resin substrate.

Then, a spray device 20 is disposed above the substrate 10.

When preparing a red sub pixel by red organic material on the substrate 10, referring to FIG. 1, first, a forward voltage is applied to the first nozzle 212, and not voltage is applied to the second nozzle 222 and the third nozzle 232; then, applying a reverse voltage to a section 11 of the substrate 10 on which red organic material is going to be deposited and applying a forward voltage to the section (comprising a section 12 on which green organic material is going to be deposited and a section 13 on which blue organic material is going to be deposited) outside the section 11 on which red organic material is going to be deposited; then, a forward voltage is applied to the first nozzle 212, such that the liquid red organic material in the first liquid supplying pipe 211 is atomized and sprayed out by electro spraying, so as to form red organic material in fog form, and the red organic material in fog form is deposited on the section 11 on which red organic material is going to be deposited; thus, a red sub pixel is formed.

When preparing a green sub pixel by green organic material on the substrate 10, referring to FIG. 2, first, a forward voltage is applied to the second nozzle 222, and no voltage is applied to the first nozzle 212 and the third nozzle 232; then, applying a reverse voltage to a section 12 of the substrate 10 on which green organic material is going to be deposited and applying a forward voltage to the section (comprising a section 11 on which red organic material is going to be deposited and a section 13 on which blue organic material is going to be deposited) outside the section 12 on which green organic material is going to be deposited; then, a forward voltage is applied to the second nozzle 222, such that the liquid green organic material in the second liquid supplying pipe 221 is atomized and sprayed out by electro spraying, so as to form green organic material in fog form, and the green organic material in fog form is deposited on the section 12 on which green organic material is going to be deposited; thus, a green sub pixel is formed.

When preparing a blue sub pixel by blue organic material on the substrate 10, referring to FIG. 1, first, a forward voltage is applied to the third nozzle 232, and not voltage is applied to the first nozzle 212 and the second nozzle 222; then, applying a reverse voltage to a section 13 of the substrate 10 on which blue organic material is going to be deposited and applying a forward voltage to the section (comprising a section 11 on which red organic material is going to be deposited and a section 12 on which green organic material is going to be deposited) outside the section 13 on which blue organic material is going to be deposited; then, a forward voltage is applied to the third nozzle 232, such that the liquid blue organic material in the third liquid supplying pipe 231 is atomized and sprayed out by electro spraying, so as to form blue organic material in fog form, and the blue organic material in fog form is deposited on the section 13 on which blue organic material is going to be deposited; thus, a blue sub pixel is formed.

According to the above description, OLED display panels are prepared by the above method, sub pixels can be prepared without masks, the spray device sprays out the organic material in fog form by electro spraying, and a higher accuracy is not necessary for the spray device, which sprays by electro spraying, such that the cost is significantly decreased.

Note that the specifications relating to the above embodiments should be construed as exemplary rather than as limitative of the present disclosure. The equivalent variations and modifications on the structures or the process by reference to the specification and the drawings of the disclosure, or application to the other relevant technology fields directly or indirectly should be construed similarly as falling within the protection scope of the disclosure.

What is claimed is:

1. A method for preparing an OLED display panel, comprising:
providing a substrate;
disposing a spray device above the substrate, and applying a forward voltage to the spray device;
applying a reverse voltage to a section of the substrate on which organic material being going to be deposited, and applying a forward voltage outside the section of substrate on which organic material being going to be deposited; and
the spray device spraying organic material in fog form, such that the organic material in fog form depositing on the section of the substrate on which organic material being going to be deposited.

2. The method for preparing an OLED display panel according to claim 1, wherein the method further comprises:
applying a reverse voltage to a section of the substrate on which red organic material is going to be deposited, and applying a forward voltage to the section outside the section of the substrate on which red organic material is going to be deposited; and
the spray device spraying red organic material in fog form, such that the red organic material in fog form is deposited on the section of the substrate on which red organic material is going to be deposited.

3. The method for preparing an OLED display panel according to claim 2, wherein the spray device comprises a first liquid supplying pipe and a first nozzle disposed beneath the first liquid supplying pipe; wherein red organic material is disposed inside the first liquid supplying pipe, and the red organic material is atomized and sprayed out by applying a forward voltage to the first nozzle.

4. The method for preparing an OLED display panel according to claim 1, wherein the method further comprises:
applying a reverse voltage to a section of the substrate on which green organic material is going to be deposited, and applying a forward voltage to the section outside the section of the substrate on which green organic material is going to be deposited; and
the spray device spraying green organic material in fog form, such that the green organic material in fog form is deposited on the section of the substrate on which green organic material is going to be deposited.

5. The method for preparing an OLED display panel according to claim 4, wherein the spray device comprises a second liquid supplying pipe and a second nozzle disposed beneath the second liquid supplying pipe; wherein green organic material is disposed inside the second liquid supplying pipe, and the green organic material is atomized and sprayed out by applying a forward voltage to the second nozzle.

6. The method for preparing an OLED display panel according to claim 1, wherein the method further comprises:
applying a reverse voltage to a section of the substrate on which blue organic material is going to be deposited, and applying a forward voltage to the section outside the section of the substrate on which blue organic material is going to be deposited; and
the spray device spraying blue organic material in fog form, such that the blue organic material in fog form is deposited on the section of the substrate on which blue organic material is going to be deposited.

7. The method for preparing an OLED display panel according to claim 6, wherein the spray device comprises a third liquid supplying pipe and a third nozzle disposed beneath the third liquid supplying pipe; wherein blue organic material is disposed inside the third liquid supplying pipe, and the blue organic material is atomized and sprayed out by applying a forward voltage to the third nozzle.

8. The method for preparing an OLED display panel according to claim 1, wherein the spray device sprays out the organic material in fog form by electro spraying.

9. An OLED display panel, wherein the OLED display panel is prepared by the method of claim 1.
